(19) United States
(12) Patent Application Publication
(10) Pub. No.: US 2026/0267239 A1
(43) Pub. Date: Sep. 10, 2026

(54) VACUUM LOAD PORTS, VACUUM-COMPATIBLE DOORS, AND METHODS FOR TRANSFERRING A RETICLE POD

(71) Applicant: ENTEGRIS, INC., Billerica, MA (US)

(72) Inventors: Tyler Monforton, Chaska, MN (US); Russ V. Raschke, Chanhassen, MN (US); Anthony M. Tieben, Belle Plaine, MN (US); Brian Wiseman, Glencoe, MN (US); Huaping Wang, Eden Prairie, MN (US); Chet Steinhagen, Minneapolis, MN (US); Caleb Elwell, Manitou Springs, CO (US)

(21) Appl. No.: 19/557,355

(22) Filed: Mar. 5, 2026

Related U.S. Application Data
(60) Provisional application No. 63/768,655, filed on Mar. 7, 2025.

(51) Int. Cl. G03F 7/00; H10P 72/10

(52) U.S. Cl. CPC G03F 7/70741; G03F 7/70841; G03F 7/7095; H10P 72/1906; H10P 72/1914

(57) ABSTRACT

Described are systems, apparatus, and methods for moving a reticle from a first space at atmospheric pressure to a second space at vacuum pressure, the systems including a vacuum load port that includes a vacuum chamber between the first space and the second space; example methods include using a vacuum-compatible door that is capable of being held under vacuum in the vacuum chamber interior.

### FIELD

This description relates to systems, apparatus, and methods for moving a reticle from a first space at atmospheric pressure to a second space at vacuum pressure, the systems including a vacuum load port that includes a vacuum chamber between the first space and the second space, and the methods including using a vacuum-compatible door that is capable of being held under vacuum in the vacuum chamber interior.

### BACKGROUND

Extreme ultraviolet lithography (also known as EUV or EUVL) is an optical lithography technology used in semiconductor device fabrication to make integrated circuits. The process uses extreme ultraviolet (EUV) wavelength radiation to produce a pattern on a surface of a microelectronic substrate. The process uses a patterned photomask or “reticle” to apply patterned radiation to a coating of photoresist solution placed on a substrate surface. Radiation is provided through or reflected off the patterned photomask to form a patterned image on the photoresist solution.

To minimize energy loss of EUV light from atmospheric gases, extreme ultraviolet (EUV) lithography processing is performed in an evacuated atmosphere, meaning a low pressure environment or a “vacuum” environment that has a pressure typically below 100 pascals. To use the reticle, it is moved from a cleanroom environment having an ambient (atmospheric) pressure condition, into the evacuated interior of the lithography tool. The reticle must be as free as possible from particle contaminants, which reduce performance and yield of a photolithograph process. Specialized devices referred to as “reticle pods” are used to contain a reticle in a clean environment and to transfer reticles between cleanroom environments and evacuated interiors of lithography tools.

Example reticle pod products have a “dual-pod” design that uses an inner reticle pod (a.k.a., “inner carrier” or “inner pod”) that encloses and protects the reticle, and a larger outer reticle pod (a.k.a., “outer shell” or “outer pod”) that contains the inner reticle pod, which holds and protects the reticle. The outer pod is a two-piece assembly that includes a lower piece referred to as a “door” that supports the inner reticle pod, and an upper piece referred to as a “dome” that covers the door to form an outer pod interior that contains the inner reticle pod.

Typically, a reticle is transferred into a lithography tool by first separating the inner reticle pod from the outer pod and then transferring the inner reticle pod by itself (without the outer pod) into the lithography tool. Current methods of moving an inner reticle pod that is contained in an outer pod, from a cleanroom into an evacuated interior of a lithography tool, require two specialized pieces of cleanroom equipment: a “load port” and a “load lock.” The load port is first used in the cleanroom to separate the inner reticle pod from the outer pod. The load port operates in the cleanroom, at atmospheric pressure, and performs automated steps of separating the dome from the outer pod door and then separating (e.g., lifting) the inner reticle pod from the door.

After using the load port to separate the inner reticle pod from the outer pod, the inner reticle pod is then transferred into the lithography tool interior using the second piece of equipment, the load lock. The load lock includes an evacuatable “vacuum chamber” that connects the clean room with the lithography tool interior and can be pressurized and de-pressurized to equalize pressure in the vacuum chamber with either the cleanroom or the lithography tool interior. The vacuum chamber is used to transfer the inner reticle pod from the ambient pressure environment of the cleanroom into the evacuated environment of the lithography tool, with pressure being equalized between the two spaces within the vacuum chamber.

Initially, the inner reticle pod is located in the cleanroom at atmospheric pressure. The inner pod holding the reticle is placed into the vacuum chamber through a first (front) door connected to the cleanroom, with the vacuum chamber at ambient pressure. A first (front) door of the vacuum chamber is then closed to form a gas-tight seal between the vacuum chamber and the cleanroom. A second (rear) door between the vacuum chamber and the interior of the lithography tool is also closed with a gas-tight seal. With both doors closed, the vacuum chamber is evacuated to a pressure that is in a range consistent with the pressure at the lithography tool interior. The second door is then opened and the inner reticle pod (or, alternately, only the reticle) can be moved from the vacuum chamber into the interior of the lithography tool. The sequence can be reversed to transfer the reticle or the reticle pod from the lithography tool interior back into the cleanroom.

Importantly, particle contamination of the reticle, the interior of the vacuum chamber, and the interior of the lithography tool must be controlled and minimized. Items that are placed in the vacuum chamber are potential sources of particle contaminants in the vacuum chamber, and may move into the lithography device that is connected to the vacuum chamber. Because a dome and a door may each be a source of particle contaminants, neither the dome nor the door is normally moved into the vacuum chamber.

### SUMMARY

The semiconductor manufacturing industry currently uses two pieces of equipment to move an inner reticle pod that holds a reticle, and that is contained in an outer pod, from a cleanroom into an interior of an extreme ultraviolet lithography tool. A first apparatus, a “load port,” separates the inner reticle pod from the outer pod. Then, a second apparatus, a “load lock,” transfers the inner reticle pod through a vacuum chamber from the cleanroom into an evacuated interior of the lithography tool. These two separate pieces of equipment, and methods of using both together during processing, have been developed and refined to be highly effective for transferring a reticle from the cleanroom into the lithography tool while preventing contaminants from being deposited onto the reticle or being introduced into the lithography tool.

Still, the ongoing need for improved efficiency of semiconductor device fabrication systems requires ever-improving equipment and methods. One opportunity to improve efficiency of lithography processes would be to combine the functions of a load port and a load lock into a single piece of equipment to replace the need for these two separate pieces of equipment. Described herein is such an apparatus, referred to as a “vacuum load port.”

A vacuum load port as described can perform functions of previous load port apparatuses and functions of previous load lock apparatuses. The vacuum load port is located in a cleanroom and connects the cleanroom to an interior of a lithography tool through a vacuum chamber. Like a load port, the vacuum load port is adapted to receive and support an outer pod that includes a door and a dome with an inner reticle pod contained in the interior of the outer pod. Also like a load port, the vacuum load port functions to separate the dome from the outer pod door to provide access to the inner reticle pod. Optionally, a vacuum load port may also function to separate the inner reticle pod from the outer pod door.

Different from a load port, but like a load lock, the vacuum load port is connected to an interior of a lithography tool through a door (or “gate”) that allows a reticle to be moved from the vacuum load port into the lithography tool interior. Also like a load lock and different from a load port, the vacuum load port has a vacuum chamber that can be evacuated to achieve a reduced pressure that is compatible with opening the vacuum load port to the evacuated interior of a lithography tool to transfer a reticle from the vacuum chamber into the evacuated lithography tool interior.

A vacuum load port as described can be a single apparatus that is capable of handling an outer pod that contains an inner reticle pod that contains a reticle to separate the door and the inner reticle pod (supported by the door) from the outer pod dome. The vacuum load port is adapted to enclose and seal the inner reticle pod and optionally the outer pod door or a portion of the outer pod door, without the dome, in a vacuum chamber. The vacuum chamber can be evacuated while containing the inner reticle pod and optionally the outer pod door or portion thereof, and the reticle or the inner reticle pod can then be moved from the evacuated vacuum chamber into the interior of the lithography tool. According to some example vacuum load ports, the load port vacuum chamber may be adapted to enclose only the inner reticle pod and not the outer pod door. In other examples, the load port vacuum chamber is adapted to enclose both the inner reticle pod and the outer pod door. In still other examples, the load port vacuum chamber is adapted to enclose the inner reticle pod and only a portion of the outer pod door, e.g., the upper door surface, that supports the inner reticle pod.

According to these latter examples, the vacuum chamber of the vacuum load port (the “load port vacuum chamber”) is adapted to enclose the outer pod door or a portion of the outer pod door. In the past, a primary concern with possible methods that place an outer pod door in a vacuum chamber of a load lock connected to a lithography tool has been the possibility of the door carrying particle contaminants into the vacuum chamber, which may then be transferred into the lithography tool. Conventional outer pod doors include mechanisms such as a latching mechanism, gaskets, and other surfaces that generate particle contaminants during use.

Accordingly, for use in a vacuum load port that is adapted to place an outer pod door or a portion of an outer pod door in a load port vacuum chamber, outer pod doors as described herein can be adapted to reduce or minimize generation of particle contaminants, or to minimize the potential transfer of particle contaminants from the door into the vacuum load port, e.g., to minimize the release of particle contaminants from the door into the vacuum load port. The present disclosure described door designs that minimize particle generation, or minimize the release of particle contaminants from the door within a vacuum chamber, or both.

An added concern with methods that place an outer pod door in a vacuum chamber of a load lock is a lack of vacuum compatibility of the door due to outgassing of volatile organic compounds, i.e., molecular contaminants, from the door when the door is held in a vacuum. To successfully enclose an outer pod door in an evacuated load port vacuum chamber, the load port vacuum chamber must be evacuated to reach a low pressure, e.g., 100, 10, or 0.1 pascals or lower. When held in the vacuum chamber at such a low pressure, the door must not outgas molecular compounds in an amount that would prevent evacuation of the vacuum chamber to the required low pressure. The door must be “vacuum-compatible,” meaning that the door must be capable of being enclosed in a vacuum chamber (e.g., having a volume of 2 or 5 cubic feet, e.g., between 2 and 5 cubic feet), and the vacuum chamber must be capable of being evacuated to a low pressure, such as 100, 10, or 0.1 pascals or lower, within a reasonable amount of time (e.g., less than 5 minutes, preferably less than 3 minutes) without volatile compounds being released from the door in an amount that would prevent the low pressure from being achieved. Accordingly, for use with a vacuum load port that is adapted to place an outer pod door or a portion of an outer pod door in a load port vacuum chamber, an outer pod door of the present description can be vacuum-compatible door according to the definition above.

In a first aspect, the disclosure relates to a method of moving an inner reticle pod from a front space at atmospheric pressure into a rear space at vacuum pressure. The method includes: enclosing the inner reticle pod and a vacuum-compatible outer pod door or a portion thereof in a vacuum chamber interior at atmospheric pressure; evacuating the vacuum chamber interior that contains the inner reticle pod and the vacuum-compatible outer pod door or portion thereof; and moving the inner reticle pod from the evacuated vacuum chamber interior into the space at vacuum pressure.

In another aspect, the disclosure relates to a method of moving an inner reticle pod from a front space at atmospheric pressure to a rear space at vacuum pressure. The method includes: moving a vacuum-compatible outer pod door and an inner reticle pod supported by the vacuum-compatible outer pod door from the front space into a vacuum chamber interior at atmospheric pressure; enclosing the inner reticle pod and the vacuum-compatible outer pod door in the vacuum chamber interior, at atmospheric pressure, and sealing the vacuum chamber interior; evacuating the vacuum chamber interior to produce vacuum pressure in the vacuum chamber interior; connecting the vacuum chamber interior to the rear space; and moving the inner reticle pod from the vacuum chamber interior into the rear space.

In another aspect, the disclosure relates to a method of moving an inner reticle pod from a front space at atmospheric pressure to a rear space at vacuum pressure. The method includes: moving an outer pod door and an inner reticle pod supported by the outer pod door from the front space into a vacuum chamber interior at atmospheric pressure; moving the outer pod door from the vacuum chamber interior into the front space; enclosing the inner reticle pod in the vacuum chamber interior, at atmospheric pressure, and sealing the vacuum chamber interior; evacuating the vacuum chamber interior to produce vacuum pressure in the vacuum chamber interior; connecting the vacuum chamber interior to the rear space; and moving the inner reticle pod from the vacuum chamber interior into the rear space.

In another aspect, the disclosure relates to a vacuum load port adapted to transfer an inner reticle pod between a front space at atmospheric pressure and a rear space at vacuum pressure. The vacuum load port includes a vacuum chamber. The vacuum chamber includes: vacuum chamber sidewalls comprising a rear opening, a vacuum chamber bottom comprising a lower opening, and a vacuum chamber top comprising an upper opening, and a vacuum chamber interior; an upper gate adapted to selectively open and close the upper opening, wherein the upper gate in an open position allows access between the front space and the vacuum chamber interior, and wherein the upper gate in a closed position creates a gas-tight seal at the upper opening between the front space and the vacuum chamber interior; a rear gate adapted to selectively open and close the rear opening, wherein the rear gate in an open position allows access between the vacuum chamber interior and the rear space, and wherein the rear gate in a closed position creates a gas-tight seal at the rear opening between the rear space and the vacuum chamber interior; a platform supported by a vertically-movable shaft that is extendable through the lower opening; and a vacuum system adapted to evacuate the vacuum chamber interior.

In another aspect the disclosure relates to a vacuum-compatible door of an outer pod that includes the vacuum-compatible door and a dome. The vacuum-compatible door includes an upper surface adapted to support an inner reticle pod, and a bottom; the dome is adapted to cover the door to define an outer pod interior adapted to contain the inner reticle pod supported by the door; the vacuum-compatible door has a low-outgassing surface; and with the vacuum-compatible door held in a vacuum chamber, the vacuum chamber can be evacuated to reach a pressure below 0.1 Pascal within 5 minutes.

In another aspect, the disclosure relates to an outer pod that includes a vacuum-compatible door and a dome. The dome is adapted to cover the vacuum-compatible door to define an outer pod interior adapted to contain an inner reticle pod; the dome includes a latching mechanism that includes an actuator and moveable contact surface, the actuator being operatively coupled to the moveable contact surface to cause the moveable contact surface to be selectively moved between a retracted position and an extended position such that when the dome is placed on the vacuum-compatible door with the moveable contact surface in the retracted position. The actuator may be moved to cause the moveable contact surface to move to the extended position and engage the vacuum-compatible door to secure the vacuum-compatible door to the dome. With the vacuum-compatible door held in a vacuum chamber, the vacuum chamber can be evacuated to reach a pressure below 0.1 Pascal within 5 minutes.

In another aspect, the description relates to an outer pod that includes a door and a dome. The dome is adapted to cover the door to define an outer pod interior adapted to contain an inner reticle pod. The door includes: a horizontally-extending upper door surface; vertically-extending door sides extending downward from the upper door surface; a door interior, and a latching mechanism at the door interior, the latching mechanism including an actuator and moveable contact surface, the actuator being operatively coupled to the moveable contact surface to cause the moveable contact surface to be selectively moved between a retracted position and an extended position such that when the dome is placed on the door plate with the moveable contact surface in the retracted position, the actuator may be moved to cause the moveable contact surface to move to the extended position and engage the dome to secure the door to the dome; and an opening below the door interior and below at least a portion of the latching mechanism to allow debris generated within the door interior to exit the door interior.

In another aspect, the disclosure relates to an outer pod that includes a vacuum-compatible door and a dome. The dome is adapted to cover the vacuum-compatible door to define an outer pod interior adapted to contain an inner reticle pod. The dome includes a generally horizontally-extending top, sidewalls that extend vertically down from the top to a dome perimeter at bottoms of the sidewalls, and a dome interior defined by the top and the sidewalls. The vacuum-compatible door includes door sides, a door bottom, and an upper surface that includes: a first sealing-compatible surface adapted to form a seal between the dome perimeter and the upper surface with the dome placed over the door, and a second sealing-compatible surface adapted to seal the upper surface in a vacuum.

In another aspect, the disclosure relates to a method of moving an inner reticle pod from a front space at atmospheric pressure to a rear space at vacuum pressure. The method includes: moving an outer pod door and an inner reticle pod supported by the outer pod door from the front space at atmospheric pressure into a vacuum load port at atmospheric pressure; forming a vacuum chamber in the vacuum load port, the vacuum chamber comprising a vacuum chamber interior that contains the inner reticle pod, with an upper surface of the outer pod door exposed to the vacuum chamber interior, with the vacuum chamber at atmospheric pressure; evacuating the vacuum chamber interior to produce vacuum pressure in the vacuum chamber interior; opening the evacuated vacuum chamber to connect the vacuum chamber interior to the rear space at vacuum pressure; and moving the inner reticle pod from the vacuum chamber interior into the rear space.

### BRIEF DESCRIPTION OF THE DRAWINGS

FIGS. 1A, 1B, and 1C show side views of an example vacuum load port as described.

FIG. 2 shows side views of an example vacuum load port as described and methods as described.

FIGS. 3A, 3B, and 3C show side views of an example vacuum load port as described.

FIG. 4 shows side views of an example vacuum load port as described and methods as described.

FIG. 5 shows side views of an example vacuum load port as described and a method as described.

FIGS. 6A and 6B show an upper perspective view and a lower perspective view of an outer pod door as described.

All figures are schematic, for purposes of example only, and are not necessarily to scale.

### DETAILED DESCRIPTION

Described as follows are vacuum load ports that are adapted and designed to perform certain combined functions of equipment referred to in the semiconductor manufacturing industry as a load port apparatus (“load port”) and a load lock apparatus (“load lock”).

The vacuum load port is located in a cleanroom and is connected to a lithography tool, for example an extreme ultraviolet lithography tool (“lithography tools”). An example vacuum load port can be a single piece of equipment that is adapted to receive, support, and manipulate an outer pod or components thereof (a dome, a door, or both), with an inner reticle pod supported by the outer pod door. An example vacuum load port can be adapted to separate the dome from the door while the door supports the inner reticle pod, and can be further adapted to transfer the inner reticle pod or a reticle contained in the inner reticle pod between a first space (a “front space,” such as a cleanroom) at atmospheric pressure and a second space (a “rear space”), such as an interior of a lithography tool, at vacuum pressure.

An example vacuum load port can be adapted to support an outer pod that includes a door and a dome with an inner reticle pod contained at an interior of the outer pod, and to separate the dome from the outer pod door while the door supports the inner reticle pod. The vacuum load port may also be adapted to enclose the reticle pod in a vacuum chamber (a “load port vacuum chamber”) and to evacuate the vacuum chamber with the reticle pod and optionally the outer pod door or a portion of the outer pod door enclosed in the load port vacuum chamber. According to some example vacuum load ports and methods, the load port vacuum chamber is adapted to enclose only the inner reticle pod with the dome and the door of the outer pod being outside of the load port vacuum chamber. According to other example vacuum load ports and methods, the load port vacuum chamber can be adapted to enclose the inner reticle pod and the outer pod door, with the dome being outside of the load port vacuum chamber. According to still other example vacuum load ports and methods, the load port vacuum chamber can be adapted to enclose the inner reticle pod and a portion of the outer pod door, such as a door upper surface that supports that inner reticle pod, while another portion of the door remains outside of the load port vacuum chamber. The load port vacuum chamber can be evacuated while containing the inner reticle pod and optionally the door or a portion of the door, and the reticle or inner reticle pod can then be moved from the evacuated vacuum chamber into the interior of the lithography tool.

Optionally and preferably, according to example methods that enclose the outer pod door in the load port vacuum chamber, the outer pod door can be adapted to reduce or minimize the generation of particle contaminants, or to reduce or minimize the potential transfer of particle contaminants from the door into the vacuum load port, e.g., minimize the movement of particle contaminants that may be present on the door, from the door, into the vacuum load port.

Also optionally and preferably, according to example methods that enclose the outer pod door or a portion of the outer pod door in the load port vacuum chamber, the outer pod door can be adapted to reduce or minimize outgassing of volatile organic compounds from the door that would prevent a step of evacuating the load port vacuum chamber to a low pressure, such as a pressure that would allow the vacuum chamber to be opened to the interior of the lithography tool. A useful or preferred door or portion of a door can be “vacuum-compatible,” meaning that the door or portion thereof is capable of being enclosed in a vacuum chamber (e.g., having a volume of 2 cubic feet, or 3, 4, or 5 cubic feet), and the vacuum chamber can be evacuated to a low pressure, such as 100, 10, or 0.1 pascals or lower, within a reasonable amount of time (e.g., less than 5 minutes, preferably less than 3 minutes) without volatile compounds being released from the door in an amount that would prevent the low pressure from being achieved.

The vacuum load pod is useful with a container, referred to as a “pod” or an “outer pod,” that is adapted to contain, store, or transport a device referred to as an “inner reticle pod,” or “reticle pod” (described in more detail herein), which is adapted to contain and protect a reticle. Example outer pods include containers referred to as “dual containment pods” that include a upper piece or “dome” and a lower piece or “door” that can be assembled by placing the dome over the door to define an interior (“outer pod interior”) that is adapted to contain an inner reticle pod supported by the door.

The door includes a substantially flat upper door surface that may be square or rectangular, and that is adapted to support an inner reticle pod. The door can include support devices (e.g., “support pins”) located on a door upper surface to support the inner reticle pod above the upper door surface. As described herein, the door may be a vacuum-compatible door that is adapted to allow for a low amount of outgassing of volatile organic compounds to thereby allow the door to be contained in a load port vacuum chamber without emitting volatile organic compounds in an amount that would prevent the formation of a low pressure (vacuum) environment in the vacuum chamber. Also as described herein, the door may be specifically designed to reduce the formation of particle contaminants or to prevent particle contaminants that are produced by the door from being released by the door, e.g., into a load port vacuum chamber.

A dome of an outer pod is a generally rectangular-shaped (e.g., square-shaped) cover that can be placed over an outer pod door to define an outer pod interior adapted to contain an inner reticle pod supported at the upper surface of the door. A dome includes a generally horizontally-extending top, four sidewalls that extend vertically down from the top to form a dome interior that is surrounded by the top and the sidewalls, and an upper interior surface that faces the outer dome interior.

A dome can include at least one and typically multiple clamps (referred to as “dome clamps”) located at the upper interior surface of the dome (a.k.a. the “dome interior surface”) and that are adapted to contact an inner reticle pod located in the outer pod interior when the dome is placed over the door with the inner reticle pod being supported by the door. A dome clamp may be of a type referred to as a “pad” or a “clamp” that has a surface that contacts an inner reticle pod located in the outer dome interior while the dome is positioned over the door and an inner reticle pod supported by the door. A dome clamp may be secured directly to the upper interior surface of the dome or may instead be secured to a dome plate that can be removably attached to the dome interior surface.

Normally, when the dome is placed over the door, opposed surfaces at the perimeters of the door and the dome contact each other to form a seal at the perimeters. According to example outer pods, a surface of either the dome or the door includes a gasket, and the other surface of the dome or the door includes a flat surface (a “sealing surface”) that contacts the gasket to form a seal between the gasket and the flat surface.

The described vacuum load ports can be useful with inner reticle pods (a.k.a. “reticle pods” for short) that are known and currently used in the semiconductor processing industry in combination with semiconductor processing equipment such as an EUV lithography tool. Examples of inner reticle pod designs are described in US patent publication 2023/0129336. An inner reticle pod can include a lower portion or “base” that functions as a lower or bottom structure of the reticle pod, and an upper portion or “cover” that functions to cover the base and enclose a reticle supported by the base. The base and the cover together define an inner reticle pod interior that is adapted to contain, enclose, and protect a reticle.

A vacuum load port can be a single piece of equipment in a cleanroom that performs functions of two previously-separate load port and vacuum port apparatuses. The vacuum load port is located in a cleanroom and connects directly to an interior of a lithography tool. In place of two separate load port and load lock apparatuses, the single vacuum load port apparatus is capable of moving an inner reticle pod that is supported by a door of an outer pod from the cleanroom into the evacuated interior of the lithography tool.

Example steps may include the following. An outer pod door and an inner reticle pod contained in the outer pod door can be moved from the front space at atmospheric pressure into the vacuum load port. The inner reticle pod and optionally the outer pod door or a portion of the outer pod door can be enclosed and sealed in an interior of a vacuum chamber of the vacuum load port at atmospheric pressure. With the inner reticle pod and optional door or portion of the door enclosed in the vacuum chamber interior, the vacuum chamber interior can be evacuated to produce a vacuum pressure in the vacuum chamber interior. The evacuated vacuum chamber can be opened to the connected lithography tool interior, which is at vacuum pressure. The reticle and optionally the inner reticle pod can then be moved from the evacuated vacuum chamber interior into the interior of the lithography tool at vacuum pressure. The steps can be reversed to move the inner reticle pod from the rear space back into the front space.

A vacuum load port includes a vacuum chamber that is adapted to form a vacuum chamber interior that is capable of enclosing an inner reticle pod and optionally an outer pod door or a portion of an outer pod door that supports the inner reticle pod. The vacuum chamber includes an opening (which may be but is not required to be at the top of the vacuum chamber) that allows the inner reticle pod and optionally the outer pod door to be moved from a front space (e.g., clean room) into the vacuum chamber. The vacuum chamber also includes a second opening (e.g., through a sidewall, and which may be referred to as a rear opening), that allows the reticle and optionally the inner reticle pod to be passed from the evacuated vacuum chamber into the lithography tool interior.

Example vacuum chambers may optionally include a third opening, e.g., a lower opening at a bottom of the vacuum chamber, that connects the vacuum chamber interior to the front space and allows the outer pod door to be removed from the vacuum chamber interior. A lower opening may also be used to vertically elevate and lower a platform within the vacuum chamber with the platform supporting the door of the outer pod. The platform may be controlled by a vertically-movable shaft that extends through the lower opening. The platform may optionally function as a lower gate to seal the lower opening. In other example vacuum load ports, the platform may be adapted to move outside of the vacuum chamber, e.g., below the vacuum chamber, to remove the outer pod door from the vacuum chamber, and the vacuum chamber incudes a separate lower gate that is adapted to close and seal the lower opening with the lower pod door being located outside of the vacuum chamber interior.

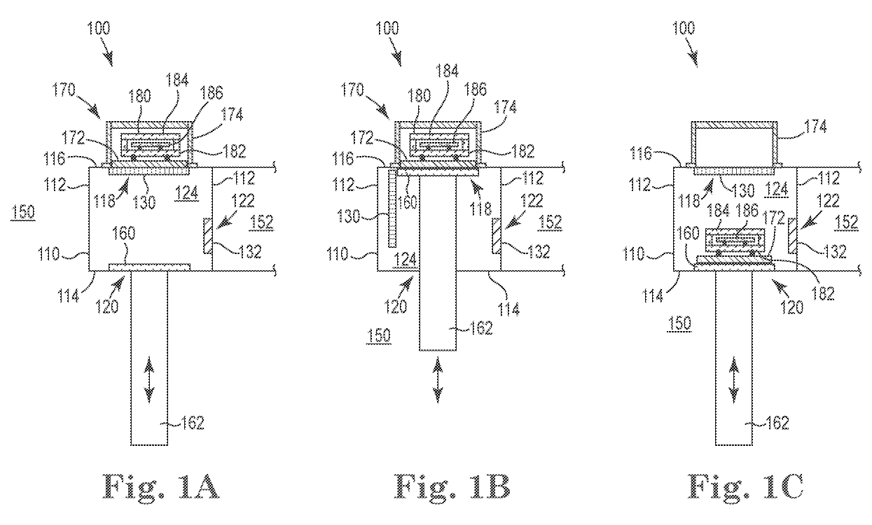

FIGS. 1A, 1B, and 1C show example vacuum load port 100. Vacuum load port 100 is located in front space 150 (e.g., a clean room) at atmospheric pressure, and includes vacuum chamber 110 which is also connected to rear space 152 (e.g., an interior of a lithography tool) at reduced (vacuum) pressure. Example vacuum load port 100 is adapted to support outer reticle pod 170 above vacuum load port 100, within front space 150. Outer reticle pod 170 includes door 172 and dome 174. Door 172 supports inner reticle pod 180, which includes inner reticle pod base 182 and inner reticle pod cover 184, with reticle 186 supported by inner reticle pod base 182 at an interior of inner reticle pod 180.

As one function of example vacuum load port 100, the vacuum load port is adapted to transfer door 172 and inner reticle pod 180 (supported by door 172) from outer space 150 into vacuum chamber 110. As a second function, vacuum load port 100 is also adapted to enclose reticle pod 180 and door 172 within a vacuum chamber interior 124, which can be evacuated to allow reticle 184 (optionally with inner reticle pod 180) to be moved from vacuum chamber 110 into evacuated rear space 152.

As shown at FIGS. 1A, 1B, and 1C, example vacuum load port 100 includes load port vacuum chamber (or “vacuum chamber” for short) 110 that is defined by sidewalls 112, vacuum chamber top 116, vacuum chamber bottom 114, upper gate 130, platform (and lower gate) 160, and rear gate 132, these structures of vacuum chamber 110 being adapted to form an enclosed vacuum chamber interior 124. Vacuum chamber top 116 includes upper opening 118, which defines a passage between vacuum chamber interior 124 and front space 150. Vacuum chamber bottom 114 includes lower opening 120, which defines a passage between vacuum chamber interior 124 and front space 150. Vacuum chamber sidewall 112 includes opening 122, which defines a passage between vacuum chamber interior 124 and rear space 152. Vacuum load port 100 also includes a vacuum system (not specifically illustrated) that is adapted to evacuate (de-pressurize) and re-pressurize vacuum chamber interior 124.

Upper gate 130 is movable and adapted to selectively open (see FIG. 1B) and close (see FIG. 1C) to form a seal at upper opening 118. In the open position, upper gate 130 allows access through upper opening 118 between front space 150 and vacuum chamber interior 124. In the closed position, upper gate 130 closes and seals upper opening 118 to create a gas-tight seal at upper opening 118 between front space 150 and vacuum chamber interior 124.

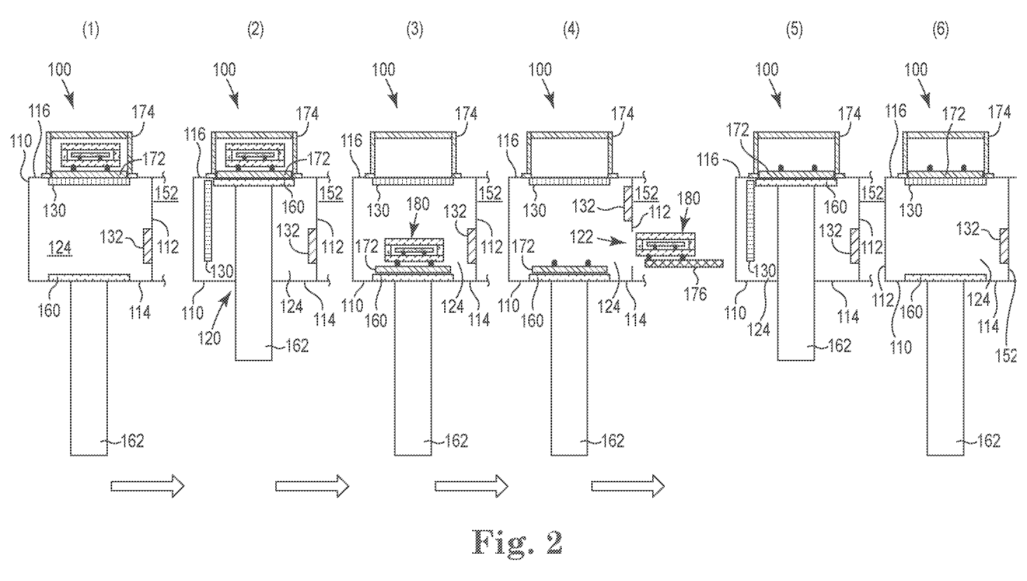

Rear gate 132 is movable and adapted to selectively open and close (and seal) rear opening 122. In an open position (see FIG. 2(4)) rear gate 132 allows access between vacuum chamber 124 and rear space 152. In a closed position (see FIG. 1C) rear gate 132 closes and seals rear opening 122 to create a gas-tight seal between rear space 152 and vacuum chamber interior 124.

Platform 160 is supported by vertically-movable shaft 162 that extends vertically through lower opening 120. Platform 160 is adapted to support door 172 of outer pod 170 above vacuum chamber 110 through upper opening 118 (see FIG. 1B) and to lower or lift outer pod door 172 between a location above vacuum chamber 110 (see FIG. 1B) and a position within vacuum chamber interior 124 (see FIG. 1C). Platform 160 may also function as a movable gate that is adapted to selectively open and close (and seal) lower opening 120 (see FIG. 1C). With gate 160 in an elevated position and with upper gate 130 in an open position (see FIG. 1B), platform 160 is elevated to support door 172. Platform 160 may be lowered to lower door 172 and inner reticle pod 180 into vacuum chamber interior 124. With platform 160 in the lowered position, platform 160 closes and seals lower opening 120 to create a gas-tight seal between front space 150 and vacuum chamber interior 124, while supporting door 172 and inner reticle pod 180 within vacuum chamber 110.

Example vacuum load port 100 of FIGS. 1A, 1B, and 1C may be used according to a method as generally described and according to the following exemplary sequence, as shown at FIG. 2 stages (1) through (6).

In an initial stage (1), platform 160 is in a lowered position and closes and seals lower opening 120; rear gate 132 is in a closed position to create a seal between vacuum chamber interior 124 and rear space 152. Outer pod 170 is located in front space 150, supported above vacuum load port 100, and upper gate 130 may be in a closed position.

In stage (2), upper gate 130 has been moved to an open position. Platform 160 is elevated to engage and support door 172 of outer pod 170 through upper opening 118. With upper gate 130 remaining open, and door 172 supported by platform 160, platform 160, while supporting door 172 (and inner reticle pod 180 supported by door 172), is lowered into vacuum chamber interior 124 while outer pod dome 174 remains outside of vacuum chamber interior 124.

In stage (3), platform 160 has been lowered to cover lower opening 120 and create a seal between outer space 150 and vacuum chamber interior 124. Upper gate 130 has been moved to a closed position to cover upper opening 118 and create a seal between outer space 150 and vacuum chamber interior 124. At this stage (3), door 172 and inner reticle pod 180 are enclosed within sealed vacuum chamber 110. Vacuum chamber interior 124 can be evacuated.

In stage (4), platform 160 and upper gate 130 remain in the closed and sealed position. Vacuum chamber interior 124 has been evacuated to a reduced pressure comparable to the pressure inside of rear space (e.g., lithography tool) interior 152. Rear door 132 can be opened to connect vacuum chamber interior 124 to rear space interior 152. Inner reticle pod 180 (or a portion thereof, or only reticle 184) can be moved into rear space 152 at vacuum pressure. As illustrated, support 176 (e.g., a robotic arm), located at rear space 152, is used to support and move inner reticle pod 180 from vacuum chamber interior 124 into rear space 152.

To reach stage (5), rear gate 132 is closed to seal rear opening 122 while upper gate 130 is also closed to seal upper opening 118, and while platform 160 is in a lowered position to close and seal bottom opening 120. Vacuum chamber 124 can be re-pressurized to atmospheric pressure. Upper gate 130 may then be moved to an open position and platform 160 and door 172 can be raised to a position above vacuum load port 110. At stage (6), upper gate 130 may then be closed and platform 160 may be lowered to cover and close lower opening 120. To remove reticle 184 and inner reticle pod 180 from rear space 152, the sequence can be reversed.

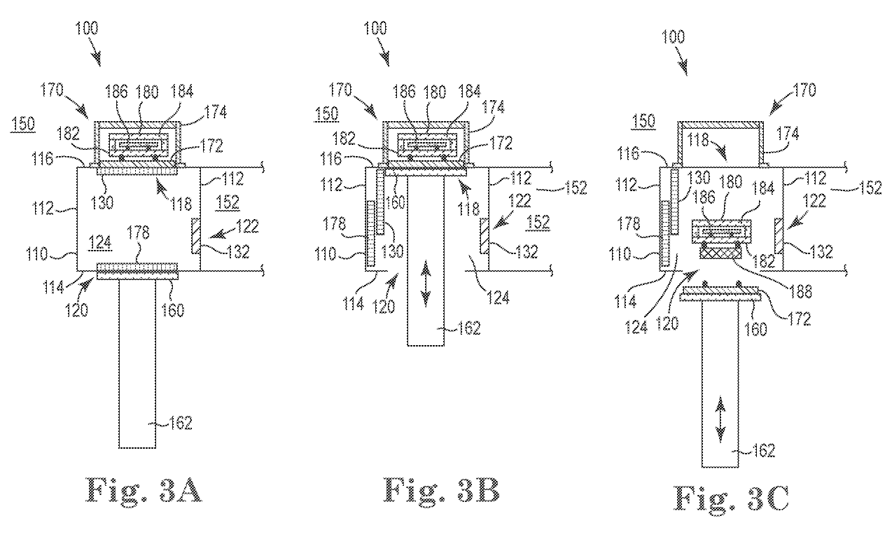

FIGS. 3A, 3B, and 3C show an alternate example of a vacuum load port 100. Different from vacuum load port 100 of FIGS. 1A, 1B, and 1C, vacuum load port 100 of FIGS. 3A, 3B, and 3C is adapted to separate outer pod door 172 from inner reticle pod 180 within vacuum chamber 110 and then remove outer pod door 172 from vacuum chamber 110 before enclosing only inner reticle pod 180 within load port vacuum chamber 124 while outer pod door 172 is positioned outside of load port vacuum chamber 124. FIGS. 3A, 3B, and 3C use the same numerical designations as FIGS. 1A, 1B, and 1C, for structures common to vacuum load port 100.

Referring to FIGS. 3A, 3B, and 3C, example vacuum load port 100 is located in front space 150 (e.g., a clean room) at atmospheric pressure and includes vacuum chamber 110 which is connected to rear space 152 (e.g., an interior of a lithography tool) at reduced (vacuum) pressure. Example vacuum load port 100 is adapted to support outer reticle pod 170, which includes door 172 and dome 174, above vacuum load port 100 within front space 150. Door 172 supports inner reticle pod 180, which includes inner reticle pod base 182 and inner reticle pod cover 184 with reticle 186 supported by inner reticle pod base 182 at an interior of inner reticle pod 180.

Example vacuum load port 100 is adapted to transfer door 172 and inner reticle pod 180 (supported by door 172) from outer space 150 into vacuum chamber 110 and then to further move outer pod door 172 to a location outside of vacuum chamber 110, e.g., below vacuum chamber 110, while inner reticle pod 180 remains in vacuum chamber 110. Accordingly, vacuum load port 100 is adapted to enclose reticle pod 180 in vacuum chamber interior 124 while outer pod door 172 is located outside of vacuum chamber interior 124. With inner reticle pod 180 enclosed in vacuum chamber interior 124, and with outer pod door 172 outside of vacuum chamber interior 124, vacuum chamber interior 124 can be evacuated and reticle 184 (optionally with inner reticle pod 180) can be moved from vacuum chamber 110 into evacuated rear space 152.

As shown at FIGS. 3A, 3B, and 3C, example vacuum load port 100 includes load port vacuum chamber (or “vacuum chamber” for short) 110 that is defined by sidewalls 112, vacuum chamber top 116, vacuum chamber bottom 114, upper gate 130, lower gate 178, and rear gate 132, these structures of vacuum chamber 110 being adapted to form an enclosed vacuum chamber interior 124. Vacuum chamber top 116 includes upper opening 118, which defines a passage between vacuum chamber interior 124 and front space 150. Vacuum chamber bottom 114 includes lower opening 120, which defines a passage between vacuum chamber interior 124 and front space 150. Vacuum chamber sidewall 112 includes opening 122, which defines a passage between vacuum chamber interior 124 and rear space 152. Vacuum load port 100 also includes a vacuum system (not specifically illustrated) that is adapted to evacuate vacuum chamber interior 124.

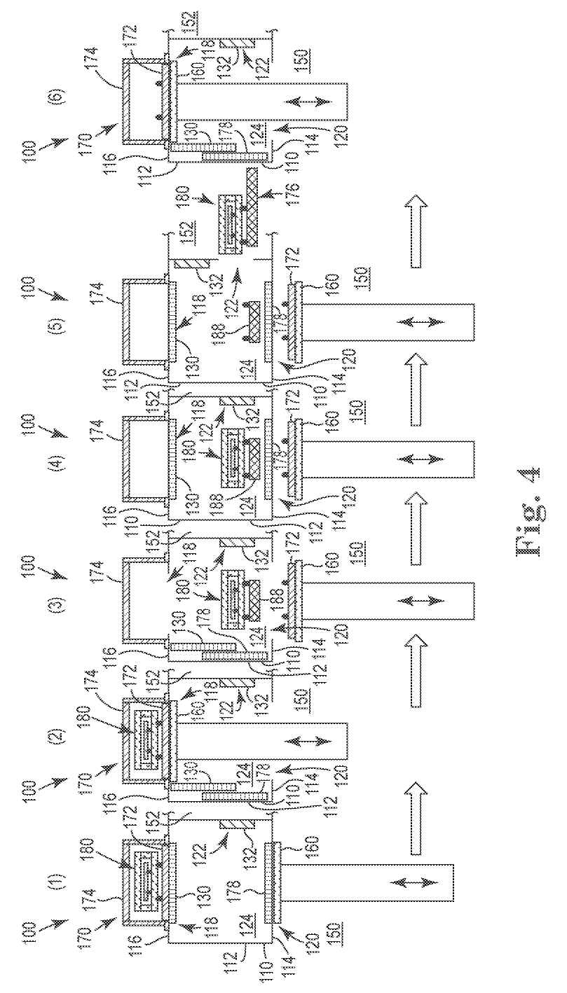

Upper gate 130 is movable and adapted to selectively open (see FIG. 3B) and close (see FIG. 4(4)) to form a seal at upper opening 118. In the open position, upper gate 130 allows access through upper opening 118 between front space 150 and vacuum chamber interior 124. In the closed position, upper gate 130 closes and seals upper opening 118 to create a gas-tight seal at upper opening 118 between front space 150 and vacuum chamber interior 124.

Rear gate 132 is movable and adapted to selectively open and close (and seal) rear opening 122. In an open position (see FIG. 4(5)), rear gate 132 allows access through rear opening 122 between vacuum chamber 124 and rear space 152. In a closed position (see FIG. 3B and FIG. 4 (4)) rear gate 132 closes and seals rear opening 122 to create a gas-tight seal between rear space 152 and vacuum chamber interior 124.

Lower gate 178 is movable and adapted to selectively open (see FIG. 3B) and close (see FIG. 4(4) and 4(5)) to form a seal at lower opening 120. In the open position, lower gate 178 allows access through lower opening 120 between front space 150 and vacuum chamber interior 124. In the closed position, lower gate 178 closes and seals lower opening 120 to create a gas-tight seal at lower opening 120 between front space 150 and vacuum chamber interior 124.

Platform 160 is supported by vertically-movable shaft 162 that is adapted to extend vertically through lower opening 120. Platform 160 is adapted to support door 172 of outer pod 170 above vacuum chamber 110 through upper opening 118 (see FIG. 3B) and to lower or lift outer pod door 172 between a location above vacuum chamber 110 (see FIG. 3B) and a position within or below vacuum chamber interior 124 (see FIG. 3C). With platform 160 in an elevated position and with upper gate 130 and lower gate 178 in open positions (see FIGS. 3B and 3C), platform 160 is elevated to support door 172 through upper opening 118. Platform 160 may be lowered to lower door 172 and inner reticle pod 180 through upper opening 118 and into vacuum chamber interior 124. Support 188 is adapted to receive and support inner reticle pod 180 within vacuum chamber interior 124. Platform 160, while supporting door 172, is then further lowered to a position outside of (e.g., below) vacuum chamber interior 124. Lower gate 178 may then be moved to a closed position with inner reticle pod 180 held by support 188 within vacuum chamber interior 124 and with outer pod door 172 being located outside of vacuum chamber interior 124 (see FIGS. 3C, 4(3), and 4(4)).

Example vacuum load port 100 of FIGS. 3A, 3B, and 3C may be used according to a method as generally described and according to the following example sequence, as shown at FIG. 4 stages (1) through (6). FIG. 4 uses the same numerical designations as FIGS. 1A, 1B, 1C, and 2, for structures common to vacuum load port 100.

In an initial stage (1), platform 160 is in a lowered position below vacuum chamber 110. Lower gate 178 is in a closed position, rear gate 132 is in a closed position, and upper gate 130 is in a closed position. Outer pod 170 is located in front space 150, supported above vacuum load port 100.

In stage (2), upper gate 130 and lower gate 178 have been moved to opened positions. Platform 160 is elevated through lower opening 120 to engage and support outer pod door 172 through upper opening 118. With upper gate 130 and lower gate 178 remaining open, and door 172 supported by platform 160, platform 160 is lowered into vacuum chamber interior 124 while outer pod dome 174 remains outside of vacuum chamber interior 124.

In stage (3), support 188 has been moved into position to support inner reticle pod 180 within vacuum chamber interior 124. Platform 160 and door 172 have been lowered to a position below and outside of vacuum chamber 110.

In stage (4), lower gate 178 has been moved to a closed position to cover lower opening 120 to create a seal between outer space 150 and vacuum chamber interior 124. Upper gate 130 has been moved to a closed position to cover upper opening 118 and create a seal between outer space 150 and vacuum chamber interior 124. At this stage (4), inner reticle pod 180 is enclosed within sealed vacuum chamber 110 while door 172 and platform 160 are located outside of vacuum chamber 124.

In stage (4), with upper gate 130 and lower gate 178 remaining in closed and sealed positions, vacuum chamber interior 124 is evacuated. In stage (5), rear door 132 can be opened and inner reticle pod 180 (or a portion thereof, or only reticle 184) can be moved into rear space 152 at vacuum pressure. As illustrated, support 176 (e.g., a robotic arm) located at rear space 152 is used to support and move inner reticle pod 180 from vacuum chamber interior 124 into rear space 152.

To reach stage (6), rear gate 132 is closed to seal rear opening 122 with upper gate 130 remaining in the closed position and with lower gate 178 remaining in the closed position and vacuum chamber 124 is re-pressurized to atmospheric pressure. Upper gate 130 and lower gate 178 may then be moved to open positions (a shown) and platform 160 can be used to raise door 172 to a position above vacuum load port 110. Platform 160 can then be lowered and upper gate 130 and lower gate 178 may then be closed. To remove reticle 184 and inner reticle pod 180 from rear space 152, the sequence can be reversed.

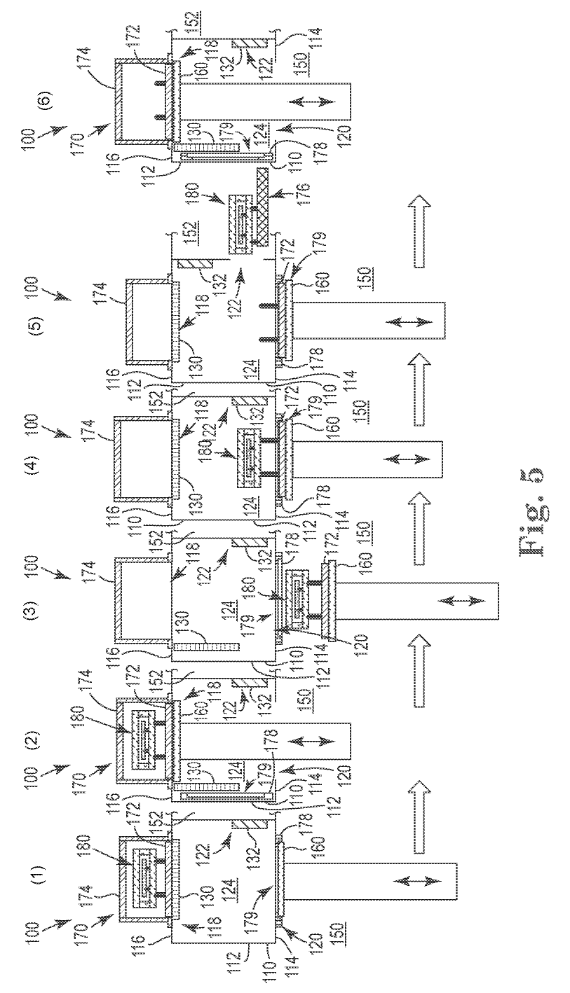

FIG. 5 shows an alternate example of a vacuum load port 100, and a method of using the vacuum load port. Different from vacuum load port 100 of FIGS. 3A, 3B, and 3C, vacuum load port 100 of FIG. 5 is adapted to separate outer pod door 172 from inner reticle pod 180, remove outer pod door 172 from vacuum chamber 110, then place inner reticle pod 180 and only a portion of outer pod door 172 within vacuum chamber interior 124 while a remaining portion of outer pod door 172 is positioned outside of load port vacuum chamber interior 124. FIG. 5 uses the same numerical designations as FIGS. 3A, 3B, and 3C, for structures common to example vacuum load port 100.

FIG. 5 shows example vacuum load port 100 similar to that of FIGS. 3A, 3B, 3C, and 4 but that includes a version of lower gate 178 that is adapted to enclose inner reticle pod 180 and a portion of door 172 within vacuum chamber interior 124. Lower gate 178 includes opening 179 and a bottom that is adapted to engage and form a seal at an upper surface of door 172 with door 172 located to engage the bottom of lower gate 178. Door 172 may include a single sealing surface or gasket that forms a seal with both outer pod door 174 and lower gate 178, or may include multiple sealing surfaces (e.g., two gaskets), one sealing surface that forms a seal with outer pod door 174 and a second sealing surface that forms a seal with lower gate 178.

Load port 100 of FIG. 5 may be used according to a method as generally described and according to the following example sequence, as shown at FIG. 5 stages (1) through (6).

In an initial stage (1), platform 160 is in a lowered position below vacuum chamber 110. Lower gate 178 is in a closed position with platform 160 below opening 170 and engaging and forming a seal at opening 179. Rear gate 132 is in a closed position, and upper gate 130 is in a closed position. Outer pod 170 is located in front space 150, supported above vacuum load port 100.

In stage (2), upper gate 130 and lower gate 178 have been moved to opened positions. Platform 160 is elevated through lower opening 120 to engage and support outer pod door 172 through upper opening 118. With upper gate 130 and lower gate 178 remaining open, and door 172 supported by platform 160, platform 160 is lowered through vacuum chamber interior 124 and through lower opening 120 to a position in outer space 150 and below lower opening 120.

In stage (3), platform 160, door 172, and inner reticle pod 180 have been lowered to a position below and outside of vacuum chamber 110. Lower gate 178 with opening 179 has been moved to a closed position to cover lower opening 120 other than at opening 179, and to create a seal at lower opening 120 between lower gate 178 and vacuum chamber bottom 114.

At stage (4), upper gate 130 has been moved to a closed position to cover upper opening 118 and create a seal between outer space 150 and vacuum chamber interior 124. Platform 160 has been elevated and door 172 covers and form a seal at opening 179. At this stage (4), inner reticle pod 180 is enclosed within sealed vacuum chamber 110, a portion of door 172 is located outside of vacuum chamber 124, and an upper portion of door 172, i.e., an upper surface of door 172, is within vacuum chamber 124. With upper gate 130 and lower gate 178 remaining in closed and sealed positions and door 172 forming a seal at opening 179, vacuum chamber interior 124 is evacuated. In stage (5), rear door 132 can be opened and inner reticle pod 180 (or a portion thereof, or only reticle 184) can be moved into rear space 152 at vacuum pressure. As illustrated, support 176 (e.g., a robotic arm) located at rear space 152 is used to support and move inner reticle pod 180 from vacuum chamber interior 124 into rear space 152.

To reach stage (6), rear gate 132 is closed to seal rear opening 122 with upper gate 130 remaining in the closed position and with lower gate 178 remaining in the closed position, with door 172 forming a seal at opening 179. Vacuum chamber 124 is re-pressurized to atmospheric pressure. Upper gate 130 and lower gate 178 may then be moved to open positions (a shown) and platform 160 can be used to raise door 172 to a position above vacuum load port 110. Platform 160 can then be lowered and upper gate 130 and lower gate 178 may then be closed. To remove reticle 184 and inner reticle pod 180 from rear space 152, the sequence can be reversed.

According to some example vacuum load ports and methods, the load port vacuum encloses the inner reticle pod and the outer pod door or a portion of the outer pod door. According to these examples, an outer pod door can be adapted to be “vacuum-compatible door,” meaning that the door is adapted to avoid outgassing of volatile organic compounds, i.e., molecular contaminants, from the door when the door is held in a vacuum. Additionally or alternately, an outer pod door can be adapted to reduce or minimize generation of particle contaminants, or to minimize the potential transfer of particle contaminants from the outer pod door into the vacuum load port, e.g., to minimize the release of particle contaminants from the door into the vacuum load port.

A vacuum-compatible outer pod door can be constructed of materials that exhibit a low or reduced amount of outgassing when exposed to a low pressure vacuum. According to certain examples, a vacuum-compatible door or components of a vacuum-compatible door may be made of a material such as a metal, a low-outgassing polymers. Examples of low-outgassing materials include metals such as aluminum and stainless steel, as well as thermoplastic and thermosetting polymers that include polyimides, fluorpolymers (e.g., polyvinylidene fluoride (PVDF), and per- and polyfluoroalkanes (PFAs)), polyetherether ketones (e.g., PEEK), polyurethanes, among others.

Additionally or alternately, a vacuum-compatible door may include a coating or a wrapping over exposed surfaces of the door or a component of the door, to prevent outgassing of volatile organic compounds from the door or the door component. A wrapping material may be a polymeric or metallized film that functions as a barrier to volatile organic compounds to prevent volatile organic compounds from passing from a material of a door into a reduced pressure atmosphere. A coating may be a coating of a polymer or metal that functions to prevent outgassing of volatile organic compounds from the door or component of the door. The coating may be applied by any useful method, such as spray coating or hydro-coating. Examples of polymers that may be useful as a coating include low-outgassing thermoplastic polymers such as polyolefins (e.g., polypropylene and polyethylene), polyethylene terephthalates (e.g., PET), polyvinyl alcohols (PVAs) for hydrodipping, polyurethanes, acrylics, and epoxies.

A door may alternately or additionally be designed to prevent the door from producing particulate debris, which may be produced by contact between moving or non-moving mechanical components of a door such as a latching mechanism or gasket. Many conventional outer pods include a latching mechanism that can be actuated to secure the dome to the door. The outer pod typically includes moving components such as gears, bearings, and arms in the door, which includes a bottom plate or cover to enclose the latching mechanism. The latching mechanism in the door can be actuated to engage the dome to secure the door to the dome. These latching mechanism are known to produce particles that can be released from the door if the door.

Example outer pods as described, for use in a method that encloses an outer pod door in a vacuum chamber of a vacuum load port, may instead include a latching mechanism that includes moving components of the latching mechanism only in the dome, with no moving components of the latching mechanism being located in the door. Particles that may be produced by movement and contact of components of the latching mechanism can be generated in the dome, and generation of particle contaminants by the door is reduced.

Alternately, moving components of a latching mechanism may be located in an outer pod door, and the door may be designed to prevent or reduce the transfer of particle contaminants generated by the latching mechanism from the door into a vacuum load port. Commonly, an outer pod door that includes movable components of a latching mechanism in the door includes a door body that has an upper door surface adapted to support an inner reticle pod on support pins located on the upper door surface, and a door interior that houses the moving components of a latching mechanism. A bottom “plate” or “cover” encloses the door interior and the moving components of the latching mechanism within the door interior. In these outer door pod designs, particle contaminants that are produced by the latching mechanism will be held within the door interior by the bottom plate.

An example outer pod door can include a similar structure, with moving components of a latching mechanism located in the door interior, but does not include a door plate that extends across the area of the door bottom, covers the door interior, and encloses the door interior at the bottom of the door body. In the absence of a door plate covering the interior at the door bottom, the door interior on the bottom of the door is uncovered over at least 50, 70, or 80 percent of the area of the door bottom.

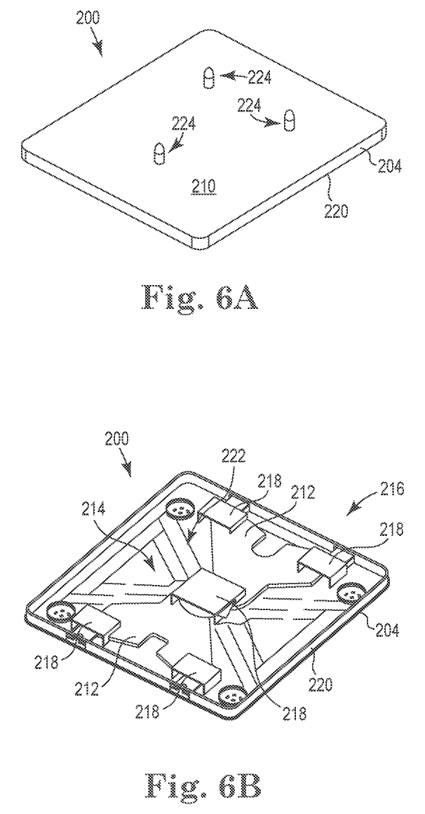

As shown at FIGS. 6A (top perspective view) and 6B (bottom perspective view), a door 200 for use in a method of the present description that encloses the door in a vacuum chamber of a vacuum load port does not include a bottom cover (or “door panel”) that encloses moving components of a latching mechanism within an a door interior. Door 200 of FIGS. 6A and 6B includes door body 220 that includes door upper surface 210 having support pins 224 adapted to support an inner reticle pod (not shown) above door upper surface 210, and door sides 204 extending below upper door surface 210 to define door interior 222. Door 200 includes moving components 212 of latching mechanism 214 within interior 222 of door body 220. Door 200 does not include a bottom cover to enclose door interior 222 and latching mechanism 214, but instead includes an opening over most of the area of the bottom of body 220 that exposes interior 222 and latching mechanism 214.

As shown at FIG. 6B, bottom 216 of door 200 is un-covered, i.e., open, over a large portion of the area bottom 216 of door 200. Moving components 212 of latching mechanism 214 and interior 222 are uncovered and accessible from a location below door 200. Optionally, one or more support segments 218, which cover a portion of interior 222, may function to provide support for moving components 212, for example to guide, support, or provide a bearing surface for a moving component 212.

The remaining area of bottom 216 remains uncovered with open access to interior 222. As a result, any particle contaminants that are produced by movement and contact between moving components 212 or latching mechanism 214 more generally will not remain and accumulate within door interior 222, e.g., by being held at interior 222 by a door plate that encloses interior 222, but will fall away from door interior 222 or may be removed from door interior 222 by cleaning at a location outside of a vacuum load port. As a result, fewer particles will collect within interior 222 of door 200 compared to a conventional outer pod door that includes a door plate that covers a bottom of a door and enclose a door interior. Door 200, with an open bottom and containing fewer particles at interior 222 can be used in a method as described, that encloses door 200 in a load port vacuum chamber, with a reduced amount of particle contaminants being carried into the load port vacuum chamber by door 200.

According to these and other examples, an outer reticle pod door and dome may alternately or additionally be designed to prevent the door from having particle debris at a seal between the door and the dome. According to conventional outer pod designs, the outer pod dome is placed over the outer pod door and opposed surfaces (“sealing surfaces”) at the perimeters of the door and the dome form a seal. Typically, the door includes a gasket that extends around the perimeter of the upper surface of the door, and the dome includes a flat sealing surface that extends around the lower perimeter of the dome. When the flat sealing surface of the lower dome perimeter contacts the gasket of the door, the flat sealing surface and the gasket form a seal. According to example outer pod doors of the present description, a door can include a flat sealing surface and no gasket, and the lower dome perimeter can include a gasket.

1. A method of moving an inner reticle pod from a front space at atmospheric pressure into a rear space at vacuum pressure, the method comprising: enclosing the inner reticle pod and a vacuum-compatible outer pod door or a portion thereof in a vacuum chamber interior at atmospheric pressure; evacuating the vacuum chamber interior that contains the inner reticle pod and the vacuum-compatible outer pod door or portion thereof; and moving the inner reticle pod from the evacuated vacuum chamber interior into the space at vacuum pressure.

2. The method of claim 1, wherein the vacuum-compatible outer pod door is a door of an outer pod that comprises the outer pod door and a dome adapted to cover the outer pod door to define an outer pod interior that contains the inner reticle pod.

3. The method of claim 1, wherein the rear space is a low pressure interior of an EUV photolithography tool.

4. The method of claim 1, comprising evacuating the vacuum chamber interior containing the vacuum-compatible door outer pod door or a portion thereof to a pressure of less than 0.1 pascal within a period of 5 minutes.

5. The method of claim 1, wherein the vacuum-compatible door comprises a low outgassing polymer.

6. The method of claim 1, wherein the vacuum-compatible door comprises a polymeric or metallized film that functions as a barrier to volatile organic compounds to prevent volatile organic compounds from passing from a material of a door into a reduced pressure atmosphere.

7. The method of claim 1, wherein the vacuum-compatible door comprises a polymeric of metal coating to prevent outgassing of volatile organic compounds from the door or component of the door into a reduced pressure atmosphere.

8. A vacuum-compatible door of an outer pod that comprises the vacuum-compatible door and a dome, wherein:
the vacuum-compatible door comprises an upper surface adapted to support an inner reticle pod, and a bottom,
the dome is adapted to cover the door to define an outer pod interior adapted to contain the inner reticle pod supported by the door,
the vacuum-compatible door comprises a low-outgassing surface, and
with the vacuum-compatible door held in a vacuum chamber, the vacuum chamber can be evacuated to reach a pressure below 0.1 Pascal within 5 minutes.

9. The vacuum-compatible door of claim 8, the low-outgassing surface comprises a metal surface, a low volatile organic compound-containing polymer surface, or both.

10. The vacuum-compatible door of claim 8, wherein the low-outgassing surface comprises a polymeric film, a metallized film, or a polymeric coating, a metal coating, or two or more of these.

11. An outer pod comprising a vacuum-compatible door and a dome, the dome being adapted to cover the vacuum-compatible door to define an outer pod interior adapted to contain an inner reticle pod, the dome comprising a latching mechanism that comprises an actuator and moveable contact surface, the actuator being operatively coupled to the moveable contact surface to cause the moveable contact surface to be selectively moved between a retracted position and an extended position such that when the dome is placed on the vacuum-compatible door with the moveable contact surface in the retracted position, the actuator may be moved to cause the moveable contact surface to move to the extended position and engage the vacuum-compatible door to secure the vacuum-compatible door to the dome,
wherein, with the vacuum-compatible door held in a vacuum chamber, the vacuum chamber can be evacuated to reach a pressure below 0.1 Pascal within 5 minutes.

12. The outer pod of claim 11, comprising:
the dome, which comprises a generally horizontally-extending top, sidewalls that extend vertically down from the top to a dome perimeter at bottoms of the sidewalls, and a dome interior defined by the top and the sidewalls,
the vacuum-compatible door, which comprises an upper door surface and a door perimeter at the upper surface, and
a gasket at the dome perimeter adapted to form a seal between the dome perimeter and a door perimeter when the dome is placed over the vacuum-compatible door.

13. The outer pod of claim 11, the door comprising one or more support segments located below a component of the latching mechanism to support the component of the latching mechanism
moving an outer pod door and an inner reticle pod supported by the outer pod door from the front space at atmospheric pressure into a vacuum load port at atmospheric pressure,
forming a vacuum chamber in the vacuum load port, the vacuum chamber comprising a vacuum chamber interior that contains the inner reticle pod, with an upper surface of the outer pod door exposed to the vacuum chamber interior, with the vacuum chamber at atmospheric pressure,
evacuating the vacuum chamber interior to produce vacuum pressure in the vacuum chamber interior,
opening the evacuated vacuum chamber to connect the vacuum chamber interior to the rear space at vacuum pressure, and
moving the inner reticle pod from the vacuum chamber interior into the rear space at vacuum pressure.
